(19) United States
(12) Patent Application Publication
(10) Pub. No.: US 2008/0211078 A1
(43) Pub. Date: Sep. 4, 2008

(54) SEMICONDUCTOR PACKAGES AND METHOD OF MANUFACTURING THE SAME

(75) Inventors: Heung-Kyu KWON, Gyeonggi-do (KR); Jeong-O HA, Chungcheongnam-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/943,088

(22) Filed: Nov. 20, 2007

(30) Foreign Application Priority Data
Mar. 2, 2007 (KR) 2007-0021172

(51) Int. Cl. H01L 23/02; H01L 21/02

(52) U.S. Cl. 257/686; 438/109; 257/E21.705; 257/E23.172

(57) ABSTRACT

A stacked semiconductor package can be formed according to principles of the present invention by stacking a plurality of semiconductor packages. A method of manufacturing the stacked semiconductor packages provides a simple manufacturing process. The stacked semiconductor package embodying these principles preferably includes a base substrate, one or more lower semiconductor packages, one or more upper semiconductor packages, and an external sealing agent. Each lower semiconductor package can include a first inner substrate, one or more first semiconductor chips electrically connected to and mounted on the first inner substrate, a first inner sealing agent sealing the first semiconductor chips, and a first contact portion. Each lower semiconductor package is preferably mounted on a portion of an upper surface of the base substrate and is electrically connected to the base substrate via the first contact portion. Each upper semiconductor package can include a second inner substrate, one or more second semiconductor chips electrically connected to and mounted on the second inner substrate, a second inner sealing agent sealing the second semiconductor chips, and a second contact portion which preferably does not contact the lower semiconductor package. Each upper semiconductor package is preferably mounted on and electrically connected to an upper surface of the base substrate via the second contact portion. One or more of the upper semiconductor packages can cover one or more of the lower semiconductor packages. The external sealing agent can cover the upper surface of the base substrate and seal the lower semiconductor package and the upper semiconductor package. A third contact portion can be formed on a lower surface of the base substrate to electrically connect the base substrate to the outside. Use of stacked semiconductor packages constructed according to these principles leads to low defect rates and high mechanical stability.

### CROSS-REFERENCE TO RELATED PATENT APPLICATIONS

This application claims the benefit of Korean Patent Application No. 10-2007-0021172, filed on Mar. 2, 2007, in the Korean Intellectual Property Office, the disclosure of which is incorporated herein by reference in its entirety.

### BACKGROUND OF THE INVENTION

1. Field of the Invention

The present invention relates generally to semiconductor packages, and more particularly, to stacked semiconductor packages and a method of manufacturing the same.

2. Description of the Related Art

As the demand for smaller-sized electronic devices, such as portable electronic devices, has increased, there has been a corresponding increase in the need to develop small, thin, and light semiconductor devices. Thus, research is being conducted on microcircuit processing techniques that increase the capacity of a semiconductor device by increasing the integration rate of a semiconductor chip in a given area. The integration rate can be increased, for instance, at the wafer manufacturing stage by increasing device integration in a semiconductor chip. This, however, requires highly-specialized and therefore very expensive manufacturing apparatuses. Accordingly, to reduce research and development time and manufacturing costs, and to improve process realization, the integration rate can be increased by stacking semiconductor chips or packages during the semiconductor package manufacturing process. Various kinds of semiconductor packages are used in digital imaging devices, MP3 players, mobile phones, and mass-capacity storage devices.

In a semiconductor package, a semiconductor chip is provided with electrical connections for connecting to an outside device and is sealed by a sealing agent so that the semiconductor chip can be protected from external environments. Semiconductor packages are generally classified based on their mounting method, for instance, as an insertion type semiconductor package or a surface mounting type semiconductor package. The insertion type semiconductor package can be a dual in-line package (DIP), a pin grid array (PGA), or the like. The surface mounting type semiconductor package can be a quad flat package (QFP), a plastic leaded chip carrier (PLCC), a ceramic leaded chip carrier (CLCC), a ball grid array (BGA), or the like.

Semiconductor packages are being continuously developed to provide multiple functions and higher capacity, while being miniaturized. A system-in-package (SIP), for example, can be relatively easily produced and includes different kinds of semiconductor devices formed in a single semiconductor package. A SIP can be realized at a relatively lower cost and with a higher reproduction rate as compared to a system-on-chip (SOC). In a SOC, different kinds of semiconductor devices are included on a single chip. As a result of these advantages, the SIP is receiving more attention.

As explained above, the SIP is a semiconductor package in which multiple conventional semiconductor packages are integrated into a single semiconductor package to significantly decrease the size of an electronic device. Conventionally, the SIP has been realized in one of two ways. In one configuration, the SIP can be a multi-chip package (MCP) formed by stacking many semiconductor chips on top of one another in a single semiconductor package. In another configuration, however, the SIP is formed as a package-on-package (POP) by stacking multiple semiconductor packages which have each been individually packaged and completely tested. The POP in particular has an expanding range of applications because many of the problems occurring when semiconductor chips are stacked can be solved. The POP can be used, for example, in a semiconductor chip card.

FIG. 1 is a somewhat schematic cross-sectional side view of a conventional semiconductor chip card 10. Referring to FIG. 1, a memory chip 13 and a controller chip 14 arc mounted on a substrate 12. The memory chip 13 and the controller chip 14 are electrically connected to electrode pads 18a, 18b on the substrate 12 with wires 16a, 16b, respectively. A sealing agent 22 is selectively formed on the substrate 12 to cover the memory chip 13 and the controller chip 14. The substrate 12 is connected to the outside by solder balls 12 or a land grid array (LGA) (not illustrated) formed below the substrate 12. The structure depicted in FIG. 1 is typically used when the substrate 12 is large or a low capacity is required.

FIG. 2 is a somewhat schematic cross-sectional side view of a conventional semiconductor package 50 in which semiconductor packages 60 and 70 having different structures are stacked together to obtain a higher capacity with improved miniaturization. In the lower semiconductor package 60, a semiconductor chip 64 is electrically connected to a substrate 62 using a wire 66, and the wire 66 and the semiconductor chip 64 are sealed using a sealing agent 69. Solder balls 68 are attached to a lower surface of the substrate 62 to connect the substrate 62 of the lower semiconductor package 60 to an external substrate (not shown). In the upper semiconductor package 70, three semiconductor chips 74A, 74B, 74C having different sizes are stacked on a substrate 72 and electrically connected to a substrate 72 via wires 76A, 76B, 76C. The stacked semiconductor chips 74A, 74B, 74C and the wires 76A, 76B, 76C are sealed using a sealing agent 79. Solder balls 78 are attached to a lower surface of the substrate 72. The solder balls 78 of the upper semiconductor package 70 are electrically connected to an upper surface of the substrate 62 of the lower semiconductor package 60, thereby producing a stacked POP structure having two semiconductor packages 60 and 70.

In the stacked semiconductor package 50 having the structure described above, the upper semiconductor package 70 is electrically connected to the outside via the substrate 62 of the lower semiconductor package 60. As a result, a wire needs to be formed on the substrate 62 of the lower semiconductor package 60 to connect to the upper semiconductor package 70. Unfortunately, this increases the complexity of manufacturing the lower semiconductor package 60 and increases defect rates. In addition, this limits the amount of structural changes that can be made to the lower semiconductor package 60. For example, a change in size or shape of the semiconductor chip 64 of the lower semiconductor package 60 may interfere with the necessary connections to the upper semiconductor package 70. Furthermore, an unsealed area between the lower and upper semiconductor packages 60, 70 may result in mechanical instability during the manufacturing process or during a subsequent operation. As a result, the semiconductor package constructed according to the prior art has low reliability.

### SUMMARY OF THE INVENTION

According to principles of the present invention, a stacked semiconductor package can be formed by stacking a plurality of semiconductor packages in a simple manufacturing process with low defect rates and high mechanical stability. A method of manufacturing the same is also provided.

According to one embodiment incorporating principles of the present invention, a stacked semiconductor package can include a base substrate, an upper semiconductor package, and a lower semiconductor package. The stacked semiconductor package can further include an external sealing agent that covers the upper surface of the base substrate and seals the lower semiconductor package and the upper semiconductor package. A third contact portion can be formed on a lower surface of the base substrate to electrically connect the base substrate to the outside.

The lower semiconductor package may include a first inner substrate, one or more first semiconductor chips electrically connected to and mounted on the first inner substrate, a first inner sealing agent sealing the first semiconductor chips, and a first contact portion. The lower semiconductor package is preferably mounted on a portion of an upper surface of the base substrate and can be electrically connected to the base substrate via the first contact portion.

The upper semiconductor package may include a second inner substrate, one or more second semiconductor chips mounted on and electrically connected to the second inner substrate, a second inner sealing agent sealing the second semiconductor chips, and a second contact portion. The second contact portion preferably does not contact the lower semiconductor package. The upper semiconductor package preferably covers the lower semiconductor package and can be electrically connected to an upper surface of the base substrate via the second contact portion. The lower semiconductor package and the upper semiconductor package can be electrically connected to each other via the base substrate.

In one specific embodiment, the one or more second semiconductor chips can include NAND and/or NOR flash memory chips. The one or more first semiconductor chips can include a flash memory controller chip (FCC) to control the one or more second semiconductor chips.

When a plurality of first semiconductor chips are provided, they can be horizontally or vertically stacked on each other on the first inner substrate. The first semiconductor chips are preferably electrically connected to the first inner substrate using wire bonding or through a via contact that penetrates the first semiconductor chips. In this stacked semiconductor package, the lower semiconductor package can, for example, be a type of ball grid array (BGA), land grid array (LGA), thin small outline package (TSOP), quad flat pack (QFP), dual-in-line package (DIP), pin grid array (PGA), or wafer level package (WLP).

Where a plurality of second semiconductor chips are provided, the second semiconductor chips can be horizontally or vertically stacked on each other on the second inner substrate. The second semiconductor chips can be electrically connected to the second inner substrate using wire bonding or through a via contact that penetrates the second semiconductor chips. The upper semiconductor package can, for instance, be a type of ball grid array (BGA), thin small outline package (TSOP), quad flat pack (QFP), dual-in-line package (DIP), pin grid array (PGA), or wafer level package (WLP). The lower semiconductor package and the upper semiconductor package may be a type of known good packages (KGPs).

An upper surface of the lower semiconductor package may be bonded to a lower surface of the upper semiconductor package by a bonding member. The height of the second contact portion can be equal to or larger than a distance between an upper surface of the base substrate and an upper surface of the lower semiconductor package. The first contact portion and the second contact portion can each, for instance, be formed as a solder ball or a lid frame. The third contact portion may be a type of line grid array (LGA) or ball grid array (BGA).

The external sealing agent preferably seals the first contact portion, an area adjacent to the first contact portion, the second contact portion, and an area adjacent to the second contact portion. The external sealing agent further preferably completely covers the upper semiconductor package.

According to another aspect of the present invention, a method of manufacturing a stacked semiconductor package can begin by preparing a base substrate. One or more lower semiconductor packages can then be mounted on a portion of the base substrate. One or more upper semiconductor packages can then be mounted on a portion of an upper surface of the base substrate to electrically connect the one or more upper semiconductor packages to the upper surface of the base substrate and to cover at least one of the lower semiconductor packages. The base substrate, the lower semiconductor package, and the upper semiconductor package can then be sealed using an external sealing agent. A third contact portion may be formed to electrically connect the base substrate to the outside on a lower surface of the base substrate. A single unit stacked semiconductor package can thereby be formed having a lower semiconductor package, an upper semiconductor package, and a third contact portion, by separating the semiconductor package from the base substrate and the external sealing agent formed on the base substrate.

The one or more lower semiconductor packages can each include a first inner substrate, one or more first semiconductor chips mounted on and electrically connected to the first inner substrate, a first inner sealing agent sealing the first semiconductor chip, and a first contact portion configured to be electrically connected to the base substrate via the first contact portion. The one or more upper semiconductor packages can have a second inner substrate, one or more second semiconductor chips mounted on and electrically connected to the second inner substrate, a second inner sealing agent sealing the second semiconductor chip, and a second contact portion that does not contact the lower semiconductor package but is instead electrically connected to the base substrate.

In the sealing process, the first contact portion, an area adjacent to the first contact portion, the second contact portion, and an area adjacent to the second contact portion can also be sealed. The upper semiconductor packages are preferably completely sealed.

Forming a single unit stacked semiconductor package can include marking areas in the external sealing agent that correspond to single unit stacked semiconductor packages. After marking the areas, a singulation process can then be performed to obtain the single unit stacked semiconductor packages. The forming of a single unit stacked semiconductor package therefore preferably includes performing a singulation process to obtain a plurality of single unit stacked semiconductor packages and labeling the external sealing agent of each of the single unit stacked semiconductor packages.

### BRIEF DESCRIPTION OF THE DRAWINGS

The above and other features and advantages of the present invention will become more readily apparent through the following detailed description of various exemplary embodiments incorporating principles of the present invention, made with reference to the attached drawings in which:

FIGS. 1 and 2 are somewhat schematic cross-sectional side views of conventional stacked semiconductor packages;

FIGS. 3 through 6 are somewhat schematic cross-sectional side views of a stacked semiconductor package incorporating principles of the present invention, which illustrate various steps in a method of manufacturing a stacked semiconductor package according to one embodiment; and

FIGS. 7 through 9 are somewhat schematic cross-sectional side views of a stacked semiconductor package incorporating additional principles of the present invention, which illustrate steps in a method of manufacturing a stacked semiconductor package according to another embodiment.

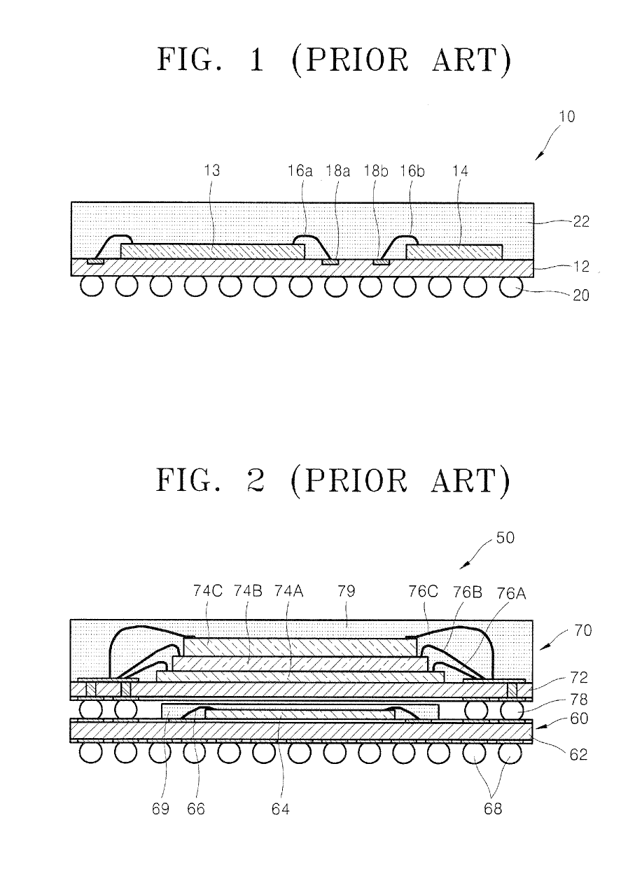

### DETAILED DESCRIPTION OF THE INVENTION

The principles of the present invention will now be described more fully with reference to the accompanying drawings, in which various exemplary embodiments incorporating principles of the present invention are shown. It should be understood, however, that the invention may be embodied in many different forms and therefore should not be construed as being limited to the specific embodiments set forth herein. Rather, these embodiments are provided to satisfy the enablement and best mode requirements by fully conveying the scope and concepts of the invention to those skilled in the art.

It should also be understood that when a layer is referred to as being “on” another layer or substrate, it can be directly on the other layer or substrate, or intervening layers may be present. In the drawings, the thicknesses and sizes of layers or elements may be exaggerated for clarity. Like reference numerals in the drawings denote like elements. The term “and/or” in the present specification indicates one or more selected from the given group. The expressions “first, second, etc.” may be used herein to explain relationships between various members, components, areas, layers and/or parts in the present specification but should not be construed as being limited to those particular members, components, areas, layer, and/or parts. Rather, these expressions are used only to differentiate a member, component, area, layer or part from another member, component, area, layer or part. Accordingly, a first member, component, area, layer or part, which will be described later, may refer to a second member, component, area, layer or part, or vice versa without departing from the teachings of the present invention.

In general, a semiconductor device can be completely manufactured using a packaging process and, in some cases, using a module manufacturing process. During the manufacturing process, the semiconductor device is subjected to many different processes, and is preferably tested at every production stage. To decrease defect rates of the semiconductor device, the production stages can include a semiconductor chip production stage, a package production stage, and a module production stage. Table 1 indicates which tests can be performed at each of these stages. In Table 1, the symbol “◯” indicates that a test is preferably performed, while the symbol “Δ” indicates that a test is preferably partly performed, and the symbol “x” indicates that a test is preferably not performed.

TABLE 1

| | | | Module |
|---|---|---|---|
| | Semiconductor Chip | Package Production | Production |
| Test | Production Stage | Stage | Stage |
| Short Circuit | ∘ | ∘ | ∘ |
| Leak Current | ∘ | ∘ | Δ |
| Function | Δ | ∘ | Δ |
| Speed | x | ∘ | Δ |

As shown in Table 1, when a stacked semiconductor package is manufactured using a package production process in which a plurality of semiconductor chips are stacked, individual semiconductor chips may have defects during the package production process even though they have already passed other tests. In addition, when a plurality of semiconductor chips are stacked on a semiconductor package that has passed tests, defects may still occur during the packaging process for the semiconductor chips, for example, such as in a wire bonding process. If this occurs, even a semiconductor package which has previously passed other tests cannot be used.

As explained above, when a stacked semiconductor package is manufactured, a plurality of semiconductor packages which have already passed tests are deposited and then repackaged to reduce costs. According to principles of the present invention, a plurality of semiconductor packages which have already passed tests can be used to manufacture a stacked semiconductor package using a simplified manufacturing process that results in a decrease in defect rates.

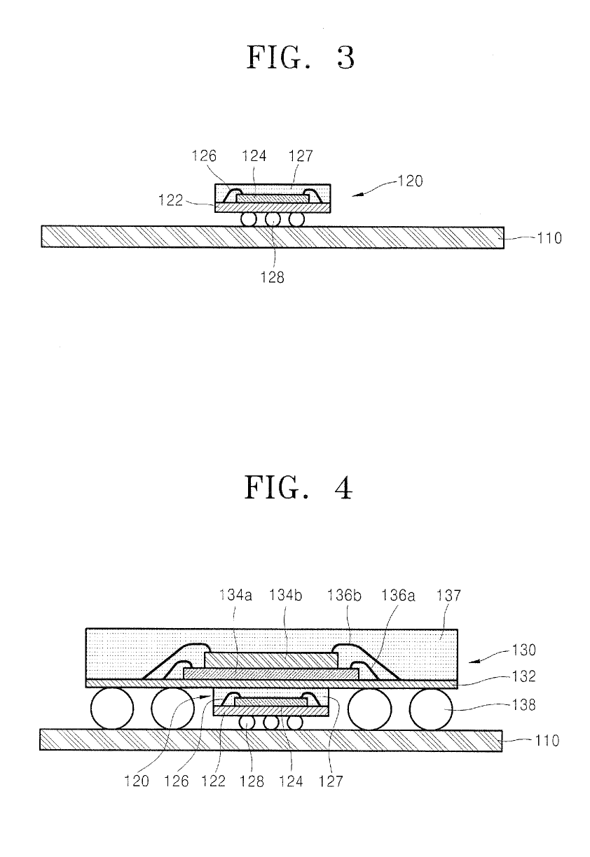

FIGS. 3 through 6 are somewhat schematic cross-sectional side views of a semiconductor package 100, illustrating various steps in a method of manufacturing a stacked semiconductor package 100 according to one embodiment incorporating principles of the present invention. Referring to FIG. 3, to manufacture a stacked semiconductor package 100, a base substrate 110 is preferably prepared. The base substrate 110 can, for instance, be a typical silicon substrate or a printed circuit board. The base substrate 110 preferably has an interconnection pattern (not shown) on its upper and lower surfaces, and inside of it, to electrically connect a lower semiconductor package 120 to an upper semiconductor package 130. The interconnection pattern can also electrically connect the lower semiconductor package 120 and the upper semiconductor package 130 to the outside.

After the base substrate is prepared, a lower semiconductor package 120 can be mounted on a portion of the base substrate 110. The lower semiconductor package 120 preferably includes a first inner substrate 122. A first semiconductor chip 124 can be electrically connected to the first inner substrate 122 through a first inner wire 126. A first inner sealing agent 127 can be provided to seal the first semiconductor chip 124. The lower semiconductor package 120 is preferably electrically connected to the base substrate 110 via a first contact portion 128.

It should be noted that the specific structure and deposition method described above with respect to the lower semiconductor package 120 illustrated in FIG. 3 is exemplary only, and the present invention is not limited thereto. For example, the first semiconductor chip 124 may instead comprise a plurality of first semiconductor chips 124. When a plurality of first semiconductor chips 124 are provided, the plurality of first semiconductor chips 124 may be horizontally or vertically stacked to each other on the first inner substrate 122. In addition, the one or more first semiconductor chips 124 may be electrically connected to the first inner substrate 122 through wire bonding or one or more via contacts that penetrate the semiconductor chips 124.

The first contact portion 128 connects the lower semiconductor package 120 to the base substrate 110 and may, for instance, include a solder ball (as illustrated in FIG. 3) or a lead frame (not shown). In general, semiconductor packages are classified according to the shape, size, manner of connection, and function of the first contact portion 128. Since, according to the principles of the present invention, the first contact portion 128 can be of various types, the lower semiconductor package 120 can, for example, be a ball grid array (BGA), a land grid array (LGA), a thin small outline package (TSOP), a quad flat pack (QFP), a dual-in-line package (DIP), a pin grid array (PGA), or a wafer level package (WLP).

In addition, the lower semiconductor package 120 can be a known good package (KGP) which has passed the tests described above after a packaging process is completed. The use of a KGP may lead to lower defect rates for complete products. It should be noted, however, that the kind and condition of the lower semiconductor package 120 described previously are exemplary only, and the present invention is not limited thereto.

The lower semiconductor package 120 mounted on the base substrate 110 may be one semiconductor package 120 or a plurality of semiconductor packages 120. A plurality of lower semiconductor packages 120 can be mounted and subjected to subsequent processes. As will be described in more detail later, a singulation process can then be performed to produce a stacked semiconductor package according to principles of the present invention.

Referring specifically to FIG. 4, after the lower semiconductor package 120 is arranged on the base substrate 110, an upper semiconductor package 130 can be deposited on a portion of the base substrate 110. The upper semiconductor package 130 can, for instance, be mounted on the base substrate 110 such that a lower semiconductor package 120 is positioned between the upper semiconductor package 130 and the base substrate 110. As shown in FIG. 4, for instance, the lower semiconductor package 120 can be positioned under the upper semiconductor package 130 in a central area. The position of the lower semiconductor package 120 in this embodiment is exemplary only, however, and the principles of the present invention are not limited thereto. An upper surface of the lower semiconductor package 120 may be bonded to a lower surface of the upper semiconductor package 130 using a bonding member (not shown). The bonding member may, for instance, be a typical bonding tape formed by coating or a liquid bonding agent.

The upper semiconductor package 130 preferably includes a second inner substrate 132. One or more second semiconductor chips 134a, 134b are preferably electrically connected to the second inner substrate 132 using respective second inner wires 136a, 136b. A second inner sealing agent 137 seals the second semiconductor chips 134a, 134b. The upper semiconductor package 130 is preferably electrically connected to the base substrate 110 via a second contact portion 138.

In the embodiment depicted in FIG. 4, two second semiconductor chips 134a, 134b are shown stacked. It should be recognized, however, that this stacked semiconductor chip structure is exemplary only, and the principles of the present invention are not limited thereto. For instance, a single second semiconductor chip could be used instead. When a plurality of second semiconductor chips 134a, 134b are provided, they may, for instance, be either horizontally or vertically stacked to each other on the second inner substrate 132. In addition, the one or more second semiconductor chips 134a, 134b can be electrically connected to the second inner substrate 132 through wire bonding. Or, as shown, for example, in FIG. 8, through a via contact 336 that penetrates the second semiconductor chips 334a, 334b.

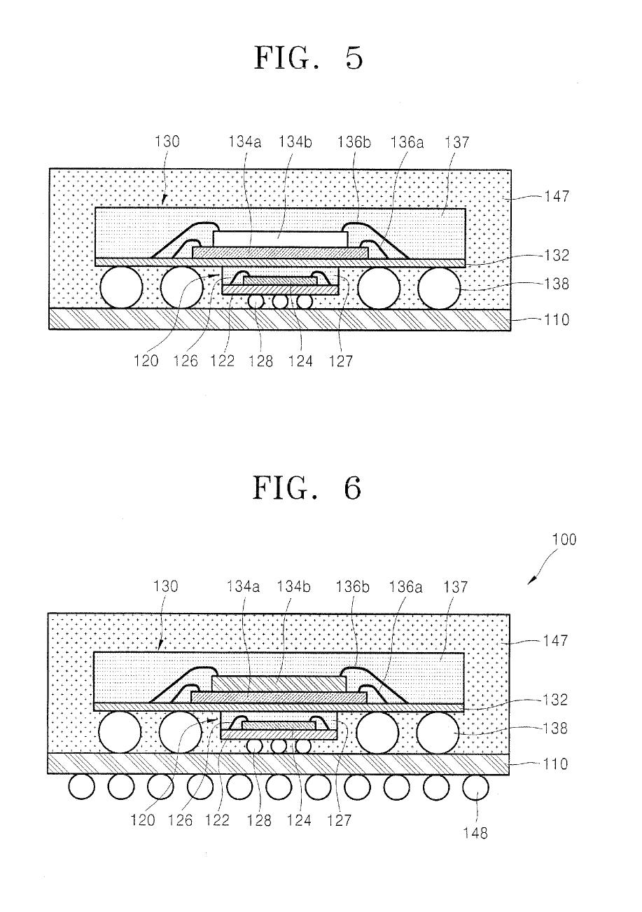

The second contact portion 138, which connects the upper semiconductor package 130 to the base substrate 110, may, for instance, include solder balls (as illustrated in FIG. 4) or a lead frame (not shown). The height of the second contact portion 138 may be equal to or larger than the distance between an upper surface of the base substrate 110 and an upper surface of the lower semiconductor package 120. After the lower semiconductor package 120 is electrically connected to the upper semiconductor package 130 via the base substrate 110, the lower semiconductor package 120 and the upper semiconductor package 130 are preferably electrically connected to the outside via a third contact portion 148 (see FIG. 6) that is formed in a subsequent process.

As described above, semiconductor packages are generally classified according to the shape, size, manner of contact, and function of the contact portion, which, in this case, is the second contact portion 138. Various types of second contact portions 138 may be provided and the upper semiconductor package 130 can therefore, for instance, be a ball grid array (BGA), a thin small outline package (TSOP), a quad flat pack (QFP), dual-in-line package (DIP), a pin grid array (PGA), or a wafer level package (WLP). In addition, the upper semiconductor package 130 can be a KGP which has passed the tests described above after a packaging process is completed. The use of a KGP may lead to lower defect rates of completed products and higher yield. These package types and configurations are exemplary only, however, and the present invention is not limited thereto.

The upper semiconductor package 130 mounted on the base substrate 110 may be one semiconductor package or a plurality of semiconductor packages 130. In the embodiment shown in FIG. 4, the upper semiconductor package 130 is positioned on the base substrate 110 in a relationship that corresponds to the position of the lower semiconductor package 120. As in a conventional packaging process, a plurality of upper semiconductor packages 130 can be stacked and subsequent processes completely performed before a singulation process is performed.

Referring to FIG. 5, an external sealing agent 147 preferably covers the base substrate 110 and seals the lower semiconductor package 120 and the upper semiconductor package 130. The external sealing agent 147 may further seal the first contact portion 128, an area adjacent to the first contact portion 128, the second contact portion 138, and an area adjacent to the second contact portion 138. In this manner, the external sealing agent 147 can completely seal the inner portion of the final stacked semiconductor package to increase mechanical stability.

To more completely seal the first contact portion 128, an area adjacent to the first contact portion 128, the second contact portion 138, and an area adjacent to the second contact portion 138, a sealing agent having high fluidity is preferably first used to seal these areas, and then the same sealing agent or a sealing agent having relatively low fluidity can be used to seal the other areas. The external sealing agent 147 may completely cover the upper semiconductor package 130 and may protect the upper semiconductor package 130 from the external environment and improve the reliability of the semiconductor package. It is therefore not necessary to use a lid to provide the benefits described above.

Referring to FIG. 6, a third contact portion 148 is preferably formed on a lower surface of the base substrate 110. The lower surface is located opposite to the upper surface on which the upper semiconductor package 130 and lower semiconductor package 120 are mounted. The third contact portion 148 preferably electrically connects the base substrate 110, and hence the upper and lower semiconductor packages 130, 120, to the outside. The third contact portion 148 can, for instance, be a line grid array (LGA) or a ball grid array (BGA). And again, as described above, semiconductor packages can be classified according to the shape, size, manner of contact, and function of the contact portion (in this case, the third contact portion 148). Accordingly, since the third contact portion 148 can be any of various types of contact portions, the complete stacked semiconductor package can be classified, for instance, as a ball grid array (BGA), a land grid array (LGA), a thin small outline package (TSOP), a quad flat pack (QFP), a dual-in-line package (DIP), a pin grid array (PGA), or a wafer level package (WLP).

A BGA requires a smaller area than a QFP or a TSOP and has a relatively large distance between lids. A BGA is therefore less affected by noise and interference and has excellent heat dissipation properties. Unfortunately, however, a BGA is weak with respect to humidity and external impacts. A TSOP has therefore generally been used in flash memories to provide improved reliability, although the TSOPs are gradually being replaced by BGAs.

Although not illustrated in the figures, the base substrate 110 and the external sealing agent 147 can be separated through a subsequent process to form a plurality of single unit stacked semiconductor packages 100. Each single unit stacked semiconductor package would preferably include a lower semiconductor package 120, an upper semiconductor package 130, and a third contact portion 148. This dividing process is called a singulation process.

Production information or the like can be marked on a portion of an upper surface of the external sealing agent 147 that corresponds to the single unit stacked semiconductor packages 100. A conventional singulation process can then be performed to separate the single unit stacked semiconductor packages 100. Alternatively, the singulation process can be performed first to separate the single unit stacked semiconductor packages 100, and then the upper surface of the external sealing agent 147 of the separated single unit stacked semiconductor packages 100 can be labeled with production information or the like. A final stacked semiconductor package 100 can produced in either manner.

A final stacked semiconductor package 100 constructed according to the principles of the present invention can be used, for instance, in a flash memory card. The second semiconductor chips 134a, 134b stacked in the upper semiconductor package 130 can, for example, be NAND and/or NOR flash memory chips, and the first semiconductor chip 124 in the lower semiconductor package 120 can include a flash memory controller chip (FCC) to control the flash memory chips 134a, 134b. Using a flash memory card embodiment constructed according to principles of the present invention, the second semiconductor chips 134a, 134b can be memory chips having the same capacity. In this case, if some of the chips malfunction, the other chips which function well can be reused in other semiconductor packages. In the conventional art, neither the defective chips or the non-defective chips could be reused.

According to principles of the present invention, for example, the second semiconductor chips 134a, 134b can each be formed by stacking four 8 giga-byte NAND memory chips, and the total memory capacity of a non-defective package should be 32 giga-bytes. If, however, during a process of forming the upper semiconductor package 130 or a stacked semiconductor package 100, one of the second semiconductor chips 134a and 134b partly malfunctions, a semiconductor memory package having a total memory capacity of 24 giga-bytes can still be obtained. This 24 giga-byte semiconductor memory package can be obtained, for instance, by providing a flash memory controller chip having a fuse-functioning circuit as the first semiconductor chip 124. Such fuse-functioning circuits can enable disconnection of the malfunctioning chips and are well known to those of ordinary skill in the art.

Accordingly, the memory capacity is preferably determined during a final testing stage, and after being tested, the marking or labeling processes can then be performed as described above. As a result, according to the principles of this invention, a semiconductor package that includes one or more malfunctioning chips can be recycled.

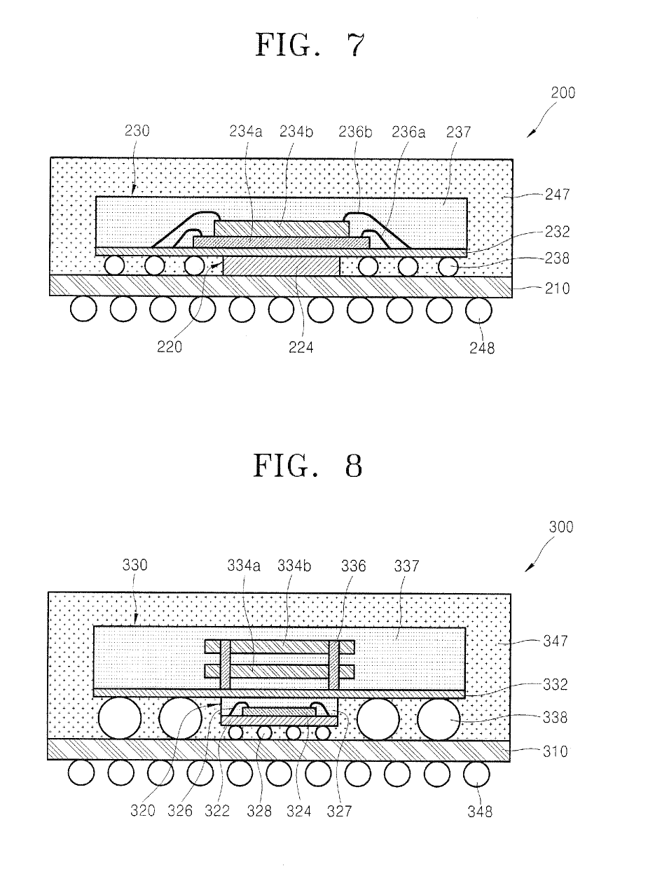

FIGS. 7 through 9 are somewhat schematic cross-sectional side views of stacked semiconductor packages 200, 300, 400 constructed according to various other embodiments incorporating principles of the present invention. The stacked semiconductor packages 200, 300, 400 are additional exemplary semiconductor packages, which vary according to the type of upper and lower semiconductor packages included in the stacked semiconductor packages.

In the following description, further description of elements in the present embodiments that are similar to the elements in the previously described stacked semiconductor package 100 will be omitted. The first digit in the reference numbers used in describing these embodiments corresponds to the related embodiment, while the second and third digits of the reference numbers are the same as those used for corresponding elements in other embodiments. For example, the base substrate 110 in the stacked semiconductor package 100 of FIGS. 3 through 6 corresponds to the base substrates 210, 310, 410 included in stacked semiconductor packages 200, 300, 400 of FIGS. 7 through 9, respectively.

Referring specifically to FIG. 7, according to one alternative embodiment, in the stacked semiconductor package 200, a lower semiconductor package 220 can be closely mounted on the base substrate 210. The lower semiconductor package 220 can, for instance, be a land grid array (LGA), a thin small outline package (TSOP), a quad flat pack (QFP), a dual-in-line package (DIP), or a pin grid array (PGA). An external sealing agent 247 need not be used between the base substrate 210 and the lower semiconductor package 220.

Referring now to FIG. 8, a stacked semiconductor package 300 represents yet another alternative embodiment. In this embodiment, a plurality of second semiconductor chips 334a, 334b included in an upper semiconductor package 330 can be electrically connected to each other and a second inner substrate 332 through a via hole 336 that penetrates the second semiconductor chips 334a, 334b.

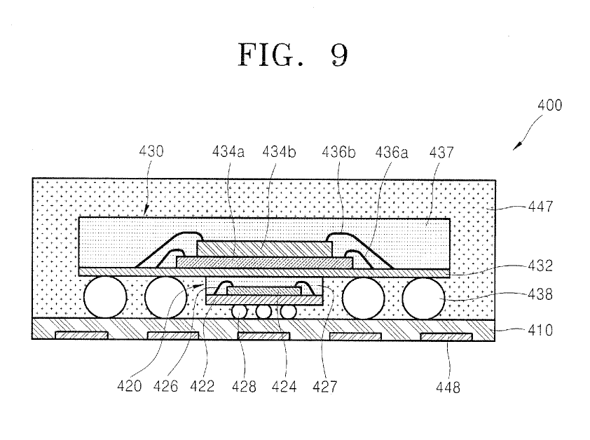

Referring finally to FIG. 9, a stacked semiconductor package 400 according to a still further embodiment includes a third contact portion 448 formed as a line grid array (LGA). In this embodiment, other than the third contact portion 448, the stacked semiconductor package 400 has the same structure as the stacked semiconductor package 100 of FIG. 6. It should be noted however, that other than the third contact portion 448, the stacked semiconductor package 400 may alternatively have a structure similar to the stacked semiconductor package 200 of FIG. 7 or the stacked semiconductor package 300 of FIG. 8.

In a stacked semiconductor package constructed according to principles of the present invention, semiconductor packages (such as KGPs) which have already been completely packaged are preferably used to construct the package on package (POP) device. This stacked semiconductor package can therefore be used to simplify a packaging process while decreasing defect rates and improving yield. In addition, when an external sealing agent is used to fill around the contact portions of the inner semiconductor packages, the stacked semiconductor package can have much higher mechanical stability than conventional stacked semiconductor packages.

In addition, when an external sealing agent is further formed on the upper semiconductor package, there is no need to form a lid, and resistance to external impacts due, for example, to handling can be improved. In addition, when a stacked semiconductor package constructed according to principles of the present invention is used in a flash memory device, stacked semiconductor package components from a defective package can be easily reused since a memory chip and a controller chip are independently packaged before the packaged memory chip and the packaged controller chip are packaged together. In addition, when semiconductor memory chips include a defective semiconductor memory chip, the other memory chips in the semiconductor package can still be used to provide a lower-capacity memory device.

While the present invention has been particularly shown and described with reference to various exemplary embodiments thereof, it will be readily understood by those of ordinary skill in the art that various changes in form and details may be made therein without departing from the spirit and scope of the present invention as defined by the following claims.

What is claimed is:

1. A stacked memory package comprising:
a base substrate;
a lower semiconductor package comprising:
a first inner substrate;
one or more first semiconductor chips electrically connected to and mounted on the first inner substrate;
a first inner sealing agent sealing the one or more first semiconductor chips; and
a first contact portion, wherein the lower semiconductor package is mounted on and electrically connected to a portion of an upper surface of the base substrate via the first contact portion;
an upper semiconductor package comprising:
a second inner substrate;
one or more second semiconductor chips electrically connected to and mounted on the second inner substrate;
a second inner sealing agent sealing the one or more second semiconductor chips; and
a second contact portion which does not contact the lower semiconductor package, wherein the upper semiconductor package is mounted on and electrically connected to an upper surface of the base substrate via the second contact portion;
an external sealing agent covering the upper surface of the base substrate and sealing the lower semiconductor package and the upper semiconductor package; and
a third contact portion formed on a lower surface of the base substrate and configured to electrically connect the base substrate to the outside.

2. The stacked semiconductor package of claim 1, wherein the lower semiconductor package and the upper semiconductor package are electrically connected to each other via the base substrate.

3. The stacked semiconductor package of claim 1, wherein the one or more second semiconductor chips comprise one or more NAND or NOR flash memory chips, and wherein the one or more first semiconductor chips comprise a flash memory controller chip (FCC) which controls the one or more second semiconductor chips.

4. The stacked semiconductor package of claim 1, wherein the one or more first semiconductor chips comprise a plurality of first semiconductor chips that are horizontally or vertically stacked on each other on the first inner substrate.

5. The stacked semiconductor package of claim 4, wherein the plurality of first semiconductor chips are each electrically connected to the first inner substrate using wire bonding or using a via contact that penetrates the first semiconductor chips.

6. The stacked semiconductor package of claim 1, wherein the lower semiconductor package comprises a ball grid array (BGA), a land grid array (LGA), a thin small outline package (TSOP), a quad flat pack (QFP), a dual-in-line package (DIP), a pin grid array (PGA), or a wafer level package (WLP).

7. The stacked semiconductor package of claim 1, wherein the one or more second semiconductor chips comprise a plurality of second semiconductor chips that are horizontally or vertically stacked on each other on the second inner substrate.

8. The stacked semiconductor package of claim 7, wherein the plurality of second semiconductor chips are electrically connected to the second inner substrate using wire bonding or using a via contact that penetrates the second semiconductor chips.

9. The stacked semiconductor package of claim 1, wherein the upper semiconductor package comprises a ball grid array (BGA), a thin small outline package (TSOP), a quad flat pack (QFP), a dual-in-line package (DIP), a pin grid array (PGA), or a wafer level package (WLP).

10. The stacked semiconductor package of claim 1, wherein the lower semiconductor package and the upper semiconductor package each comprise a known good package (KGP).

11. The stacked semiconductor package of claim 1, wherein an upper surface of the lower semiconductor package is bonded to a lower surface of the upper semiconductor package with a bonding member.

12. The stacked semiconductor package of claim 1, wherein a height of the second contact portion is equal to or larger than a distance between an upper surface of the base substrate and an upper surface of the lower semiconductor package.

13. The stacked semiconductor package of claim 1, wherein each of the first contact portion and the second contact portion comprises solder balls or a lead frame.

14. The stacked semiconductor package of claim 1, wherein the external sealing agent seals the first contact portion, an area adjacent to the first contact portion, the second contact portion, and an area adjacent to the second contact portion.

15. The stacked semiconductor package of claim 1, wherein the external sealing agent completely covers the upper semiconductor package.

16. The stacked semiconductor package of claim 1, wherein the third contact portion comprises a line grid array (LGA) or a ball grid array (BGA).

17. A method of manufacturing a stacked semiconductor package, the method comprising:
preparing a base substrate;
mounting a plurality of lower semiconductor packages on a portion of the base substrate, said lower semiconductor packages having a first inner substrate, one or more first semiconductor chips mounted on and electrically connected to the first inner substrate, a first inner sealing agent sealing the first semiconductor chip, and a first contact portion configured to be electrically connected to the base substrate via the first contact portion;
mounting a plurality of upper semiconductor packages on a portion of an upper surface of the base substrate, said upper semiconductor packages having a second inner substrate, one or more second semiconductor chips mounted on and electrically connected to the second inner substrate, a second inner sealing agent sealing the second semiconductor chip, and a second contact portion configured not to contact the lower semiconductor package, and wherein the second contact portion is further configured to electrically connect to the upper surface of the base substrate, and wherein further, one or more of the plurality of upper semiconductor packages covers at least one of the lower semiconductor packages;
covering the base substrate and sealing the lower semiconductor package and the upper semiconductor package with an external sealing agent;
forming a third contact portion on a lower surface of the base substrate, wherein the third contact portion electrically connects the base substrate to the outside; and
forming one or more single unit stacked semiconductor packages by separating the base substrate and the external sealing agent formed on the base substrate, wherein each single unit stacked semiconductor package respectively comprises at least one lower semiconductor package, at least one upper semiconductor package, and at least one third contact portion.

18. The method of claim 17, wherein the lower semiconductor package and the upper semiconductor package are electrically connected to each other via the base substrate.

19. The method of claim 17, wherein the one or more second semiconductor chips comprise one or more NAND or NOR flash memory chips, and wherein the one or more first semiconductor chips comprise a flash memory controller chip (FCC) that controls the one or more second semiconductor chips.

20. The method of claim 17, wherein the lower semiconductor package comprises a ball grid array (BGA), a land grid array (LGA), a thin small outline package (TSOP), a quad flat pack (QFP), a dual-in-line package (DIP), a pin grid array (PGA), or a wafer level package (WLP).

21. The method of claim 17, wherein the upper semiconductor package comprises a ball grid array (BGA), a thin small outline package (TSOP), a quad flat pack (QFP), a dual-in-line package (DIP), a pin grid array (PGA), or a wafer level package (WLP).

22. The method of claim 17, wherein the lower semiconductor package and the upper semiconductor package each comprise a known good package (KGP).

23. The method of claim 17, wherein an upper surface of the lower semiconductor package is bonded to a lower surface of the upper semiconductor package with a bonding member.

24. The method of claim 17, wherein the height of the second contact portion is equal to or larger than a distance between an upper surface of the base substrate and an upper surface of the lower semiconductor package.

25. The method of claim 17, wherein during the sealing step, the first contact portion, an area adjacent to the first contact portion, the second contact portion, and an area adjacent to the second contact portion are sealed.

26. The method of claim 17, wherein during the sealing step, the plurality of upper semiconductor packages are completely covered.

27. The method of claim 17, wherein, the third contact portion is a line grid array (LGA) or ball grid array (BGA.)

28. The method of claim 17, wherein the step of forming one or more single unit stacked semiconductor package comprises:
marking respective areas corresponding to each of the single unit stacked semiconductor packages in the external sealing agent; and
performing a singulation process to obtain the single unit stacked semiconductor packages.

29. The method of claim 17, wherein the step of forming one or more single unit stacked semiconductor package comprises:
performing a singulation process to obtain single unit stacked semiconductor packages; and
labeling the external sealing agent of each single unit stacked semiconductor package.
